(19) United States
(12) Patent Application Publication
(10) Pub. No.: US 2025/0199055 A1
(43) Pub. Date: Jun. 19, 2025

(54) DETECTION SYSTEM

(71) Applicant: Industrial Technology Research Institute, Hsinchu (TW)

(72) Inventors: Fu-An Tu, Hsinchu County (TW); Ming-Hsien Wu, Tainan City (TW)

(73) Assignee: Industrial Technology Research Institute, Hsinchu (TW)

(21) Appl. No.: 18/966,126

(22) Filed: Dec. 3, 2024

Related U.S. Application Data
(60) Provisional application No. 63/607,563, filed on Dec. 8, 2023.

(51) Int. Cl. G01R 31/26

(52) U.S. Cl. CPC G01R 31/2635

(57) ABSTRACT

A detection system is provided for detecting an element under test. The detection system includes an illumination module, a sensing module, and a processing part. The illumination module provides an illumination beam to the element under test. The illumination beam includes sub-beams of different wavelengths. The sensing module senses the element under test to obtain an electrical signal, and includes a carrier mechanism, a first substrate, a control layer, a sensing layer, and an electrical connection element. The sensing layer is disposed on a first surface of the first substrate, and has a sensing surface that is the surface closest to the element under test in the sensing module. The electrical connection element is electrically connected to the sensing layer and the control layer. The processing part is electrically connected to the illumination module and the sensing module, and configured to generate a sensing result according to the electrical signal.

### CROSS-REFERENCE TO RELATED APPLICATION

This application claims the priority benefit of U.S. provisional application Ser. No. 63/607,563, filed on Dec. 8, 2023. The entirety of the above-mentioned patent application is hereby incorporated by reference herein and made a part of this specification.

### BACKGROUND

### Technical Field

The disclosure relates to an electronic apparatus, and particularly relates to a detection system.

### Description of Related Art

As the display technology related to light-emitting diodes continues to develop, the size of light-emitting diodes has gradually reduced to a few micrometers. For this reason, when detecting light-emitting diodes, the probe of the detection device may not easily align with the electrodes of the light-emitting diodes, and the size of the probe tip needs to be designed to match the size of the electrodes of the light-emitting diodes. Due to the difficulty in manufacturing a probe with an extremely small tip and the need for the probe tip to contact the electrodes of the light-emitting diodes during the detection process, it is very likely to have defects in the electrodes of the light-emitting diodes and/or cause wear of the probe. Moreover, in the existing detection methods for light-emitting diodes, the probe is required to sequentially contact multiple electrodes of multiple light-emitting diodes, making the detection process labor-intensive and time-consuming.

Driven by applications such as AI, backend data centers will handle massive amounts of data. Optical signals have characteristics such as large bandwidth, low power consumption, and longer transmission distance, which may also solve the signal loss and heat problems currently encountered with copper wires. Therefore, how to apply laser miniaturization to accelerate the integration of light sources with silicon chips, while also allowing for massive production to reduce costs, as well as how to detect a large number of light sources with small sizes, is one of the goals in this field.

### SUMMARY

The disclosure provides a detection system which is capable of ensuring that circuits or other components do not come into contact with an element under test, thereby realizing a non-contact detection method that is beneficial to rapid massive detection.

The disclosure provides a detection system for detecting an element under test. The detection system includes an illumination module, a sensing module, and a processing part. The illumination module is configured to provide an illumination beam to the element under test. The illumination beam includes multiple sub-beams of different wavelengths. The sensing module is configured to sense the element under test to obtain an electrical signal. The sensing module includes a carrier mechanism, a first substrate, a control layer, a sensing layer, and an electrical connection element. The first substrate is disposed on the carrier mechanism. The first substrate has a first surface and a second surface opposite to each other, and the second surface faces the carrier mechanism. The control layer is disposed on the second surface of the first substrate. The sensing layer is disposed on the first surface of the first substrate. The sensing layer has a sensing surface, and the sensing surface is the surface closest to the element under test in the sensing module. The electrical connection element is electrically connected to the sensing layer and the control layer. The processing part is electrically connected to the illumination module and the sensing module, and configured to generate a sensing result according to the electrical signal.

Based on the above, in the detection system of the disclosure, the detection system includes an illumination module, a sensing module, and a processing part. The illumination module is configured to provide an illumination beam to an element under test. The sensing module is configured to sense the element under test to obtain an electrical signal, and the processing part is configured to generate a sensing result according to the electrical signal. The sensing module includes a carrier mechanism, a first substrate, a control layer, a sensing layer, and an electrical connection element. The sensing layer has a sensing surface, and the sensing surface is the surface closest to the element under test in the sensing module. Thus, the circuits or other components in the sensing module do not exceed the height of the sensing surface, to ensure that the circuits or other components do not come into contact with the element under test, thereby realizing a non-contact detection method that is beneficial to rapid massive detection.

To make the above-mentioned features and advantages of the disclosure easier to understand, embodiments will be described in detail below with reference to the accompanying drawings.

### BRIEF DESCRIPTION OF THE DRAWINGS

FIG. 1 is a schematic view of the detection system according to an embodiment of the disclosure.

FIG. 2 is a schematic view of the detection system according to another embodiment of the disclosure.

FIG. 3A and FIG. 3B are respectively a side view and a top view of the sensing module in FIG. 1.

FIG. 4A to FIG. 4C are side views showing the manufacturing process of the sensing module in FIG. 3A.

FIG. 5A and FIG. 5B are respectively schematic diagrams based on intensity of the electrical sub-signal versus voltage for the detection system in FIG. 1 detecting different elements under test.

FIG. 6 is a schematic diagram of the electrical signals from elements under test of different quality.

FIG. 7 is a schematic view of the detection system according to another embodiment of the disclosure.

FIG. 8A and FIG. 8B are respectively a side view and a top view of the sensing module in FIG. 7.

FIG. 9A to FIG. 9D are side views showing the manufacturing process of the sensing module in FIG. 8A.

FIG. 10A and FIG. 10B are respectively a side view and a top view of the sensing module according to another embodiment of the disclosure.

FIG. 11A to FIG. 11D are side views showing the manufacturing process of the sensing module in FIG. 10A.

### DESCRIPTION OF THE EMBODIMENTS

The disclosure can be understood by referring to the following detailed description in conjunction with the accompanying drawings. It should be noted that, for ease of understanding and simplicity of the drawings, several drawings of the disclosure may only depict a part of the electronic device, and specific elements in the drawings may not be drawn to actual scale. Furthermore, the quantity and size of each element in the drawings are for illustrative purposes only and are not intended to limit the scope of the disclosure.

The directional terms mentioned in the disclosure, such as “up”, “down”, “front”, “back”, “left”, and “right”, may only refer to the directions in the accompanying drawings. Therefore, the directional terms used are for illustrative purposes and are not intended to limit the disclosure. Each of the accompanying drawings illustrates the general features of the methods, structures and/or materials used in specific embodiments. Nevertheless, these drawings should not be interpreted as defining or limiting the scope or nature covered by these embodiments. For example, for clarity, the relative sizes, thicknesses, and positions of various layers, areas and/or structures may be reduced or enlarged.

The terms such as “about”, “equal”, “equivalent” or “same”, “substantially”, and “approximately” may generally be interpreted as within 20% of a given value or range, or interpreted as within 10%, 5%, 3%, 2%, 1%, or 0.5% of a given value or range.

It should be noted that, in the following embodiments, features from several different embodiments may be replaced, recombined, or mixed to form other embodiments without departing from the spirit of the disclosure. Features from various embodiments may be arbitrarily combined and used as long as they do not contradict the spirit of the disclosure or conflict with each other.

The following provides exemplary embodiments of the disclosure, with the same reference numerals used in the drawings and descriptions to represent identical or similar parts.

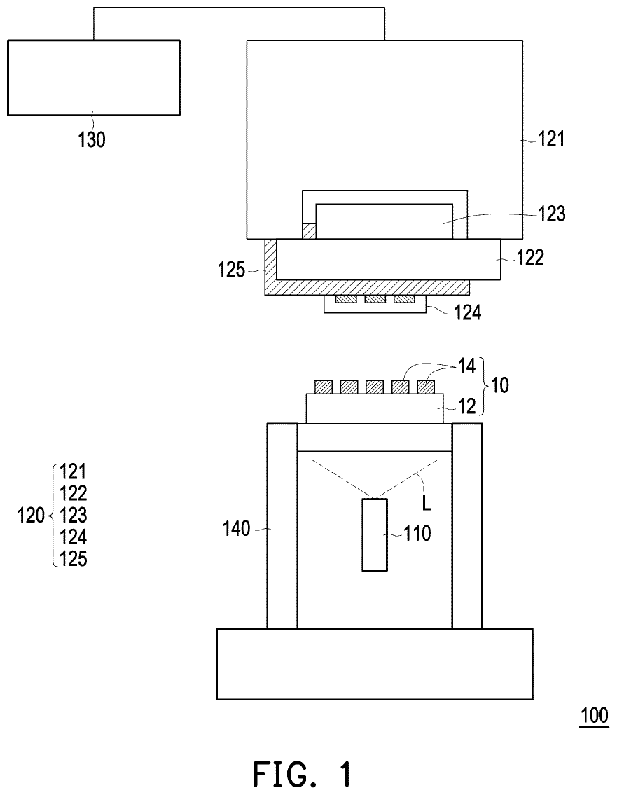

FIG. 1 is a schematic view of the detection system according to an embodiment of the disclosure. Referring to FIG. 1, this embodiment provides a detection system 100 for detecting an element under test 10. Specifically, the detection system 100 may detect the quality of light emission from the element under test 10, which allows inspection of the production process of the element under test 10 and thereby improves the overall yield. In this embodiment, the detection system 100 includes an illumination module 110, a sensing module 120, and a processing part 130.

For example, in this embodiment, the element under test 10 may include a carrier 12 and multiple light-emitting units 14. The carrier 12 is configured to carry the light-emitting units 14, and may be, for example, a wafer, but the disclosure is not limited thereto. The light-emitting units 14 are disposed on the carrier 12, and the light-emitting units 14 may be, for example, micro LEDs, mini LEDs, or other suitable light-emitting diodes. In this embodiment, the light-emitting unit 14 may be a type of horizontal light-emitting diode, but the disclosure is not limited thereto. In other embodiments, the light-emitting units 14 may be vertical light-emitting diodes, flip-chip light-emitting diodes, or other suitable light-emitting diodes.

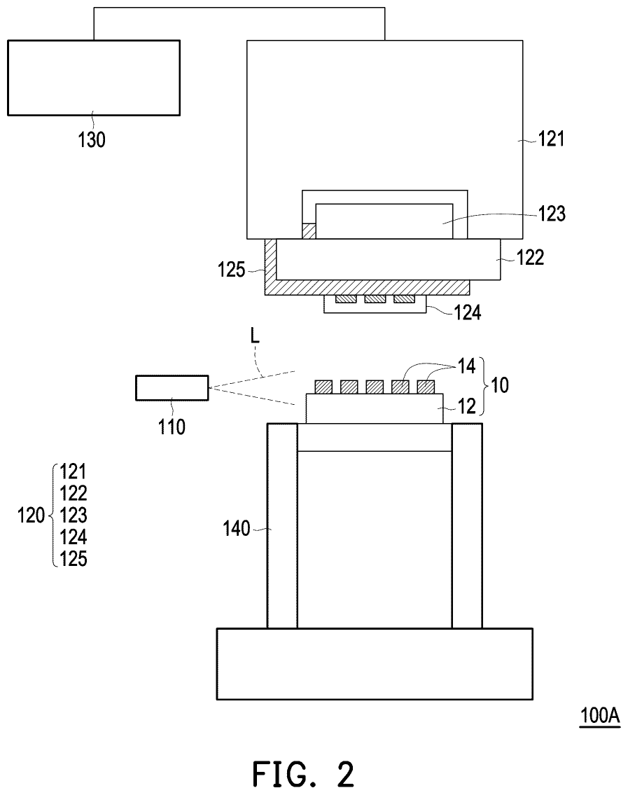

FIG. 2 is a schematic view of the detection system according to another embodiment of the disclosure. Referring to FIG. 1 and FIG. 2, the illumination module 110 is configured to provide an illumination beam L to the element under test 10. Specifically, the illumination module 110 may simultaneously emit the illumination beam L to the light-emitting units 14 on the element under test 10, and the illuminance of the illumination beam L emitted to each light-emitting unit 14 may be substantially equal, but the disclosure is not limited thereto. The illumination beam L emitted by the illumination module 110 may, for example, cause the light-emitting unit 14 to generate a photovoltaic effect. Therefore, the wavelength of the illumination beam L may be, for example, shorter than the wavelength of the light emitted by the light-emitting unit 14. The illumination beam L includes multiple sub-beams of different wavelengths, and these sub-beams are within a specific wavelength range. In this embodiment, the number of the sub-beams of different wavelengths may be, for example, two. For example, in a case where the light-emitting units 14 on the element under test 10 are blue light-emitting units, the illumination beam L may use sub-beams of two different wavelengths from 360 nm to 450 nm for illumination. In a case where the light-emitting units 14 are green light-emitting units, the illumination beam L may use sub-beams of two different wavelengths from 500 nm to 600 nm for illumination. In a case where the light-emitting units 14 are red light-emitting units, the illumination beam L may use sub-beams of two different wavelengths from 600 nm to 650 nm for illumination. In a case where the light-emitting units 14 are infrared light-emitting units, the illumination beam L may use sub-beams of two different wavelengths from 1000 nm to 1600 nm for illumination. In other words, the illumination module 110 may design an appropriate illumination beam L for detection according to light-emitting units of different wavelengths. In this embodiment, the illumination module 110 is disposed on a side of the element under test 10 that is away from the sensing module 120 (that is, the element under test 10 is located between the illumination module 110 and the sensing module 120), and the illumination beam Lis transmitted to the element under test 10 from the side of the element under test 10 that is away from the sensing module 120, but the disclosure is not limited thereto. For example, in this embodiment, the element under test 10 is disposed on a stage 140, and the illumination module 110 is disposed on the stage 140 to transmit the illumination beam L from below the element under test 10. In another embodiment, the illumination module 110 is disposed on a lateral side of the element under test 10 to transmit the illumination beam L to the element under test 10 from a side surface of the element under test 10, as shown in a detection system 100A in FIG. 2, but the disclosure is not limited thereto, either.

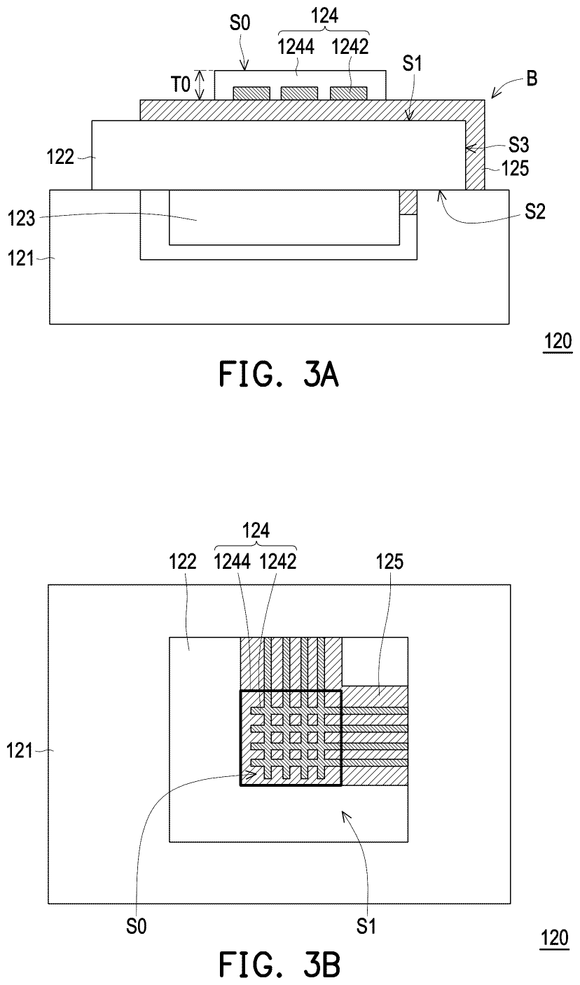

FIG. 3A and FIG. 3B are respectively a side view and a top view of the sensing module in FIG. 1. Referring to FIG. 1, FIG. 3A, and FIG. 3B, the sensing module 120 is configured to sense the element under test 10 to obtain an electrical signal. The processing part 130 is electrically connected to the illumination module 110 and the sensing module 120, and is configured to generate a sensing result according to the electrical signal obtained by the sensing module 120. The processing part 130 may be, for example, a central processing unit (CPU), a microprocessor, a digital signal processor (DSP), a programmable controller, a programmable logic device (PLD), other similar devices, or combinations of these devices, but the disclosure is not limited thereto. Furthermore, in an embodiment, various functions of the processing part 130 may be implemented as multiple codes. These codes may be stored in a memory to be executed by the processing part 130. Alternatively, in an embodiment, various functions of the processing part 130 may be implemented as one or more circuits. The disclosure is not intended to limit whether the various functions of the processing part 130 are implemented in a software or hardware manner.

The sensing module 120 includes a carrier mechanism 121, a first substrate 122, a control layer 123, a sensing layer 124, and an electrical connection element 125. The carrier mechanism 121 may be, for example, a motorized frame structure configured to carry and move the other elements in the sensing module 120. The carrier mechanism 121 may be provided with a driving element, or the carrier mechanism 121 may be designed to connect with external equipment to realize a power function, but the disclosure is not limited thereto.

The first substrate 122 is disposed on the carrier mechanism 121. The first substrate 122 has a first surface S1 and a second surface S2 opposite to each other, and the second surface S2 faces the carrier mechanism 121. The material of the first substrate 122 may include, for example, ceramic, quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), other suitable materials, or combinations of the foregoing materials, but the disclosure is not limited thereto.

The control layer 123 is disposed on the second surface S2 of the first substrate 122. The control layer 123 is electrically connected to the sensing layer 124. The control layer 123 may include, for example, a processing part (not shown) and a memory part (not shown), and the processing part may be configured to process the electrical signal provided from the sensing layer 124. The memory part may be configured to store the electrical signal provided from the sensing layer 124 and/or a signal processed by the processing part. In this embodiment, the control layer 123 may determine whether the capacitance value of each sensing pattern 1242 in the sensing layer 124 is lower than a preset capacitance value. Specifically, the preset capacitance value of the sensing pattern 1242 may be stored in the memory part of the control layer 123. By comparing the changed capacitance value of each sensing pattern 1242 in the sensing layer 124, it is possible to obtain the electrical properties of each of the light-emitting units 14, thereby determining whether each light-emitting unit 14 in the element under test 10 is defective.

The sensing layer 124 is disposed on the first surface S1 of the first substrate 122. The thickness T0 of the sensing layer 124 is greater than or equal to 10 μm, and the sensing layer 124 has a sensing surface S0. The sensing surface S0 is a surface closest to the element under test 10 in the sensing module 120. In other words, the circuits or other components in the sensing module 120 do not exceed the height of the sensing surface S0, to ensure that the circuits or other components do not come into contact with the element under test 10, thereby realizing a non-contact detection method that is beneficial to rapid massive detection. Specifically, the sensing layer 124 includes the sensing pattern 1242 and a light-transmitting layer 1244. The sensing pattern 1242 is electrically connected to the electrical connection element 125. The light-transmitting layer 1244 covers the sensing pattern 1242, and the sensing surface S0 is located on a surface of the light-transmitting layer 1244. The light-transmitting layer 1244 may be, for example, glass, with a surface designed with optical microstructures or a rough surface, but the disclosure is not limited thereto.

The electrical connection element 125 is electrically connected to the sensing layer 124 and the control layer 123. The electrical connection element 125 may be, for example, a Flexible Printed Circuit (FPC). In this embodiment, the electrical connection element 125 is disposed on the first substrate 122 and is connected to the first surface S1 and the second surface S2 of the first substrate 122. In other words, the electrical connection element 125 has at least one bending point B. Specifically, in this embodiment, the first substrate 122 has a third surface S3 connected to the first surface S1 and the second surface S2. The third surface S3 is perpendicular to the first surface S1 and the second surface S2, and the electrical connection element 125 is also connected to the third surface. Therefore, the sensing layer 124 and the control layer 123 may be electrically connected through the electrical connection element 125, while keeping the sensing surface S0 of the sensing layer 124 as the surface closest to the element under test 10 in the sensing module 120.

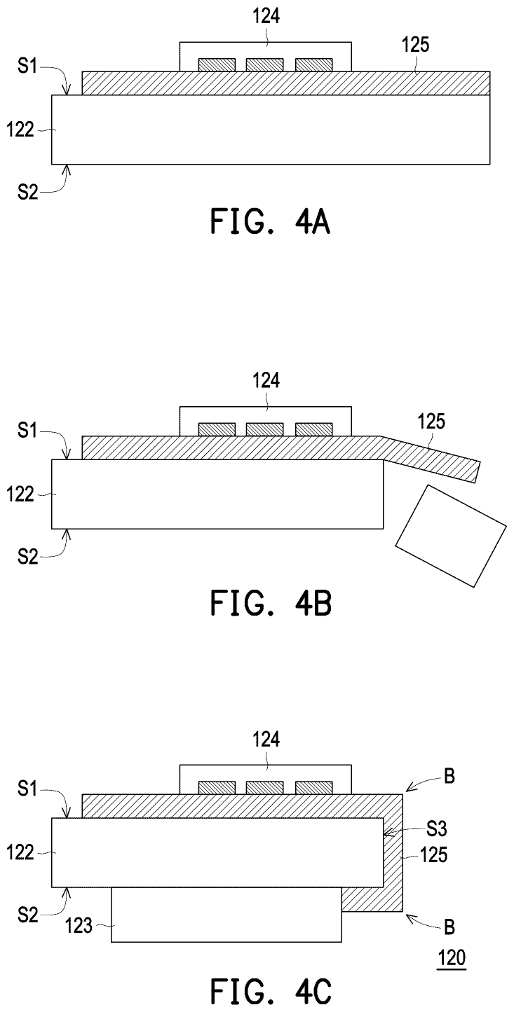

FIG. 4A to FIG. 4C are side views showing the manufacturing process of the sensing module in FIG. 3A. Referring to FIG. 3A to FIG. 4C, in this embodiment, the manufacturing process of the sensing module 120 may include, for example, first, disposing the electrical connection element 125 on the first surface S1 of the first substrate 122, and disposing the sensing layer 124 on the electrical connection element 125, as shown in FIG. 4A. Then, after the above step, a part of the first substrate 122 is removed to allow the electrical connection element 125 to be bent, as shown in FIG. 4B. Subsequently, after the above step, the control layer 123 is disposed on the second surface S2 of the first substrate 122, and the electrical connection element 125 is connected to the third surface S3 and the second surface S2 of the first substrate 122, so as to be connected to the control layer 123, as shown in FIG. 4C.

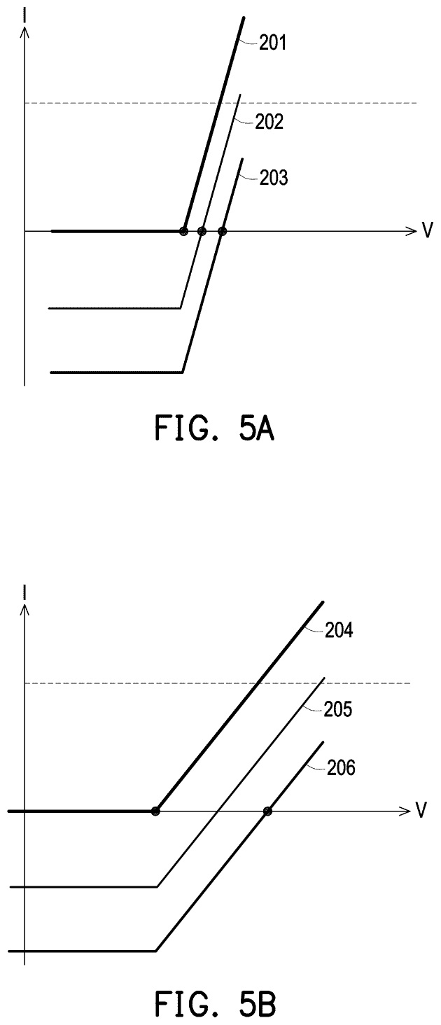

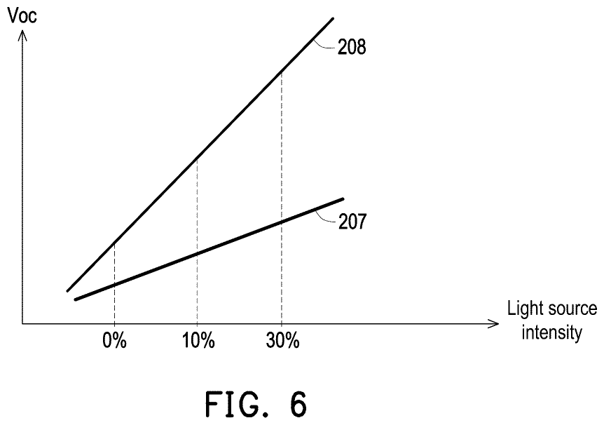

FIG. 5A and FIG. 5B are respectively schematic diagrams based on intensity of the electrical sub-signal versus voltage for the detection system in FIG. 1 detecting different elements under test. FIG. 6 is a schematic diagram of the electrical signals from elements under test of different quality. Referring to FIG. 1 and FIG. 5A to FIG. 6, the illumination module 110 emits the illumination beam L to the element under test 10, and the light-emitting unit 14 in the element under test 10 absorbs photons from the illumination beam L to generate electrons (that is, generating a photovoltaic effect), causing the charge distribution between the positive and negative electrodes of the light-emitting unit 14 to change, thereby generating an electric field (or potential difference) between the positive and negative electrodes. Therefore, the positive and negative electrodes of the sensing pattern 1242 in the sensing layer 124 may each detect the potential value of the positive and negative electrodes of the light-emitting unit 14 and/or the electric field (or potential difference) generated between the positive and negative electrodes of the light-emitting unit 14, causing a change in the capacitance value of the positive and negative electrodes of the sensing pattern 1242 in the sensing module 120. The control layer 123 may generate a resulting electrical signal based on the electrical change of the sensing module 120, which enables the processing part 130 to determine whether the element under test 10 is defective. During detection, in a case where the difference between light intensities of the illumination beam Lis greater than 10%, the sensing accuracy may be further improved. For example, in a case where the illumination module 110 respectively provides the illumination beam L with light intensities of 0%, 10%, and 30% to a defect-free element under test 10, different electrical properties may be obtained, as shown by line segments 201, 202, and 203 in FIG. 5A. In a case where the illumination module 110 respectively provides the illumination beam L with light intensities of 0%, 10%, and 30% to a defective element under test 10, different electrical properties (for example, the slope of current versus voltage) may be obtained, as shown by line segments 204, 205, and 206 in FIG. 5B. Therefore, the sensing module 120 may further obtain multiple corresponding electrical sub-signals, and then obtain open-circuit voltage data under the same electrical conditions (for example, current) with different light intensity illuminations, forming a characteristic electrical signal (for example, the slope of open-circuit voltage versus different light intensity illuminations), as shown by line segments 207 and 208 in FIG. 6, wherein line segment 207 represents a defect-free element under test 10, and line segment 208 represents a defective element under test 10. In this way, characteristic data may be obtained by providing the illumination beam L with different intensities, thereby determining whether the element under test 10 is defective.

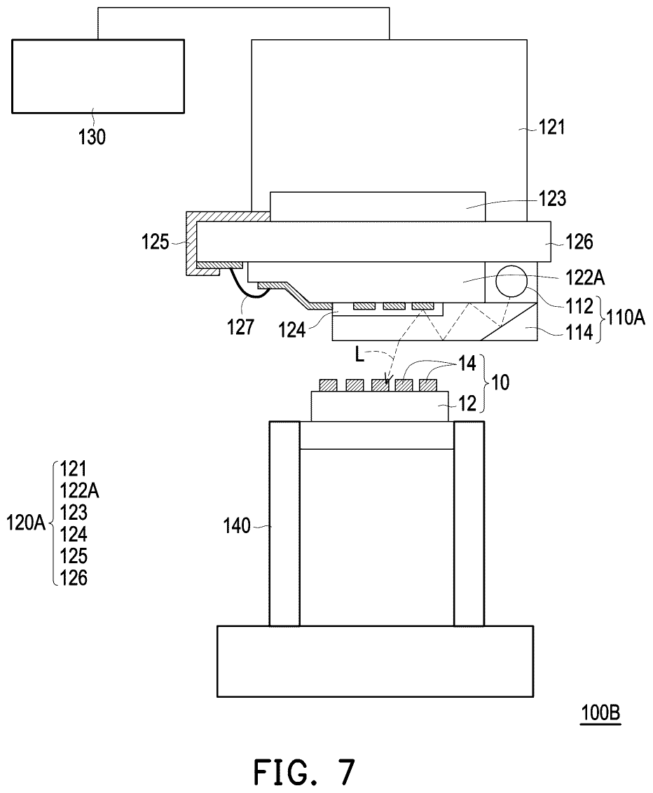

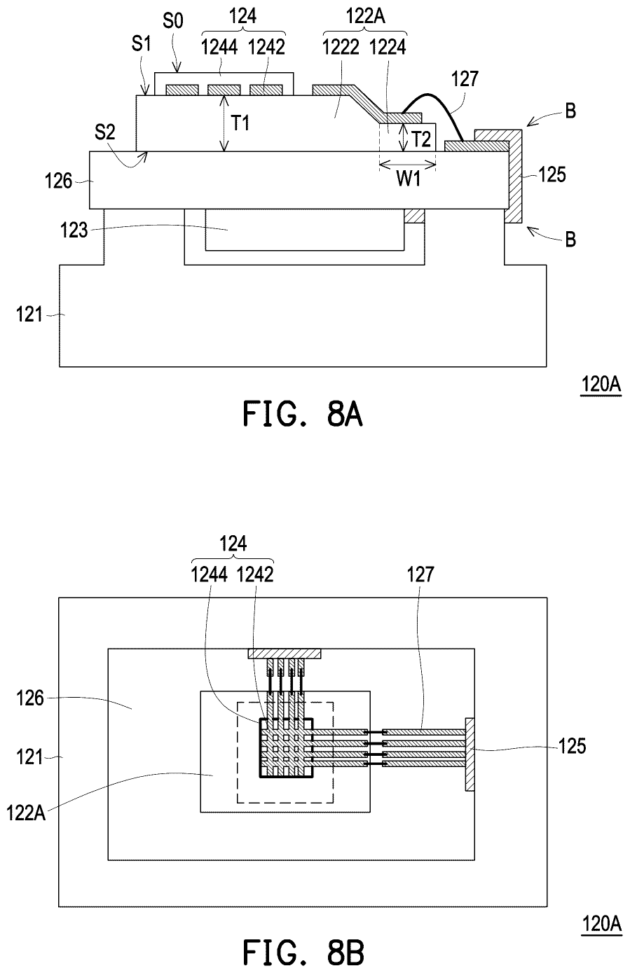

FIG. 7 is a schematic view of the detection system according to another embodiment of the disclosure. FIG. 8A and FIG. 8B are respectively a side view and a top view of the sensing module in FIG. 7. The detection system 100B of this embodiment is similar to the detection system 100 in FIG. 1. The difference lies in that, in this embodiment, the sensing module 120A further includes a second substrate 126 and a conductive structure 127. In this embodiment, the second substrate 126 may be, for example, a Printed Circuit Board (PCB), disposed between the first substrate 122A and the control layer 123. The conductive structure 127 may be, for example, a metal bonding wire and/or a conductor structure, connected to the first substrate 122A and the second substrate 126. In this embodiment, the electrical connection element 125 is connected to the second substrate 126 and is connected to the conductive structure 127. In other words, the conductive structure 127 is connected between the sensing layer 124 and the electrical connection element 125, as shown in FIG. 8A and FIG. 8B.

More specifically, in this embodiment, the first substrate 122A includes a first portion 1222 and a second portion 1224 connected to each other. The thickness T1 of the first portion 1222 is greater than the thickness T2 of the second portion 1224. The sensing layer 124 is connected to the first portion 1222, and the conductive structure 127 is connected to the first surface S1 and continuously connected to the first portion 1222 and the second portion 1224. The electrical connection element 125 is connected to the conductive structure 127 located on the second portion 1224. More specifically, in this embodiment, the width W1 of the second portion 1224 is greater than 20 μm, and the vertical distance between the first surface S1 located on the second portion 1224 and the sensing surface S0 is greater than 50 μm. In this way, the metal bonding wire structure in the conductive structure 127 is formed on the thinner second portion 1224, so that the conductive structure 127 does not exceed the height of the sensing surface S0, which ensures that the circuits or other components do not come into contact with the element under test 10, thereby realizing a non-contact detection method that is beneficial to rapid and massive detection.

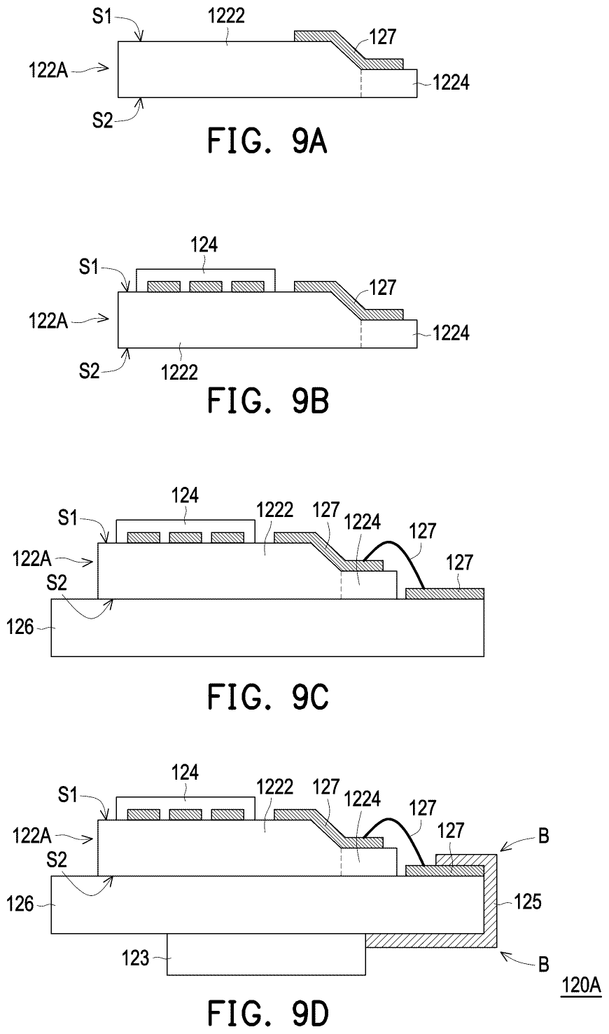

FIG. 9A to FIG. 9D are side views showing the manufacturing process of the sensing module in FIG. 8A. Referring to FIG. 8A to FIG. 9D, in this embodiment, the manufacturing process of the sensing module 120A may include, for example, disposing a part of the conductive structure 127 on the first portion 1222 and the second portion 1224 of the first substrate 122A, as shown in FIG. 9A. The sensing layer 124 is disposed on the first portion 1222 of the first substrate 122A, as shown in FIG. 9B. A combination of the sensing layer 124 and the first substrate 122A is disposed on the second substrate 126, and another part of the conductive structure 127 is formed on the surface of the second substrate 126 not covered by the first substrate 122A, forming a bonding wire structure to electrically connect the conductive structure 127 at two locations, as shown in FIG. 9C. The control layer 123 is disposed on the second substrate 126, and the electrical connection element 125 is disposed to connect the control layer 123 and the conductive structure 127 located on the second substrate 126, as shown in FIG. 9D.

Further referring to FIG. 7, in this embodiment, the illumination module 110A is disposed on the sensing module 120A. The illumination module 110A includes a light-emitting element 112 and a light-guiding element 114. The light-emitting element 112 provides the illumination beam L, and the light-guiding element 114 is disposed on the transmission path of the illumination beam L to guide the illumination beam L from a side of the element under test 10 that is close to the sensing module 120A to the element under test 10. The reflective surface of the light-guiding element 114 may be designed with optical microstructures or a rough surface, but the disclosure is not limited thereto. In this embodiment, the light-guiding element 114 of the illumination module 110A may be co-formed with the light-transmitting layer 1244 of the sensing layer 124, but the disclosure is not limited thereto. In this way, the illumination beam L may form a surface light source with higher uniformity, thereby enhancing the overall detection effect. In a different embodiment, the sensing module 120A of this embodiment may also replace the sensing module 120 in the detection system 100 of FIG. 1 while retaining the illumination module 110 shown in FIG. 1, but the disclosure is not limited thereto.

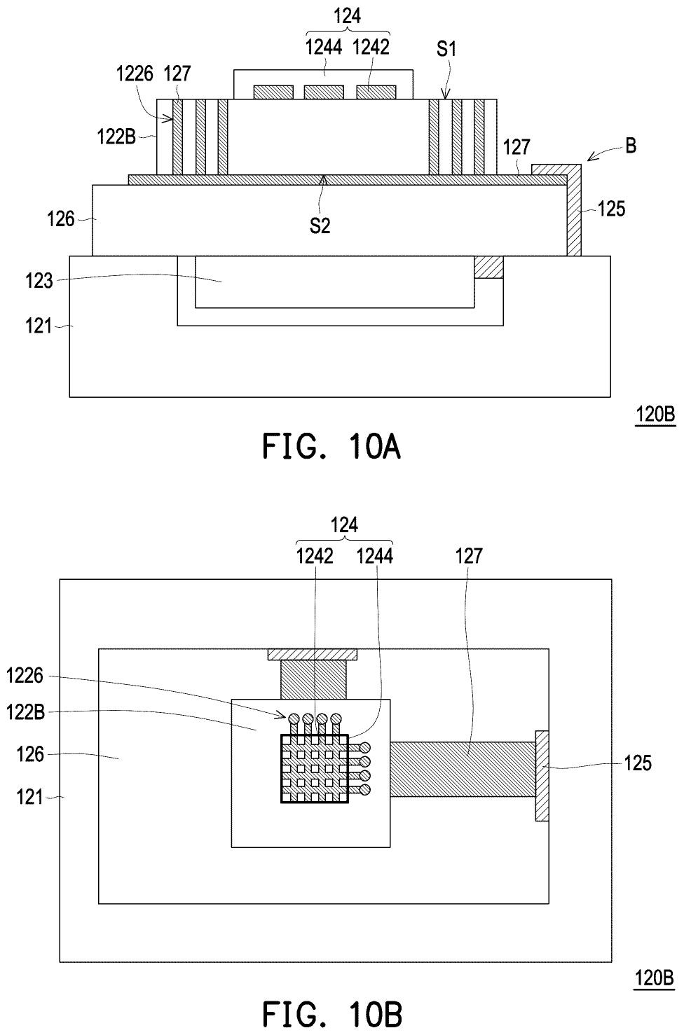

FIG. 10A and FIG. 10B are respectively a side view and a top view of the sensing module according to another embodiment of the disclosure. Referring to FIG. 10A and FIG. 10B, the sensing module 120B shown in this embodiment is similar to the sensing module 120 shown in FIG. 3A. The difference lies in that, in this embodiment, the sensing module 120B further includes a second substrate 126 and a conductive structure 127. In this embodiment, the second substrate 126 may be, for example, a Printed Circuit Board, disposed between the first substrate 122B and the control layer 123. The conductive structure 127 may be, for example, a metal bonding wire and/or a conductor structure, connected to the first substrate 122B and the second substrate 126. In this embodiment, the electrical connection element 125 is connected to the second substrate 126 and is connected to the conductive structure 127. In other words, the conductive structure 127 is connected between the sensing layer 124 and the electrical connection element 125, as shown in FIG. 10A and FIG. 10B.

Specifically, in this embodiment, the first substrate 122B has multiple through-holes 1226, and the conductive structure 127 is connected to the second surface S2 of the first substrate 122B and is also located in the through-holes 1226 to connect the sensing layer 124. In this way, any structure does not exceed the height of the sensing surface S0, which ensures that the circuits or other components do not come into contact with the element under test 10, thereby realizing a non-contact detection method that is beneficial to rapid massive detection. The sensing module 120B of this embodiment may replace the detection system 100 shown in FIG. 1, the detection system 100A shown in FIG. 2, or the detection system 100B shown in FIG. 7, but the disclosure is not limited thereto.

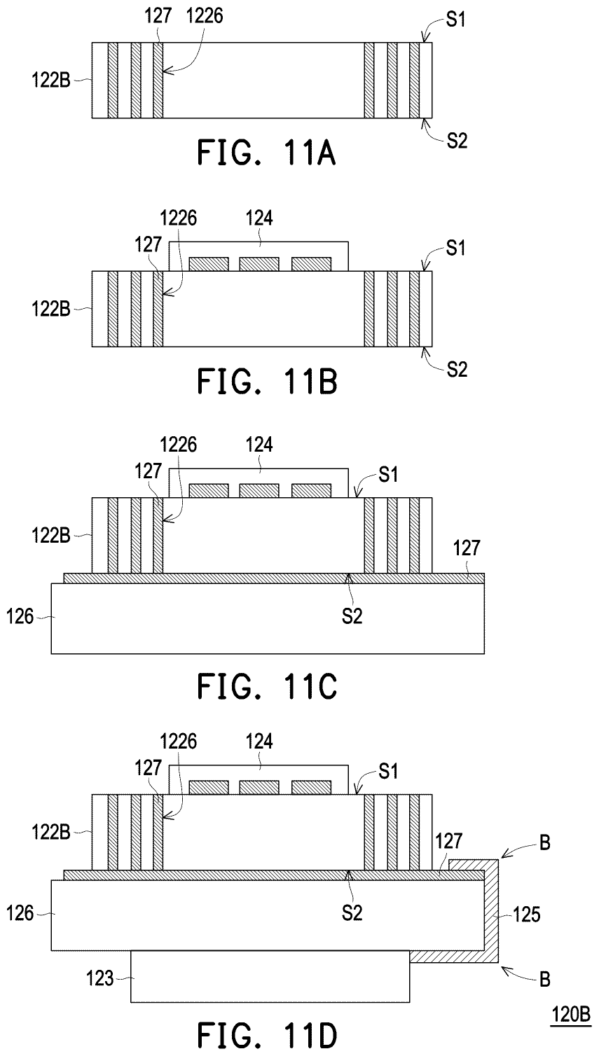

FIG. 11A to FIG. 11D are side views showing the manufacturing process of the sensing module shown in FIG. 10A. Referring to FIG. 10A to FIG. 11D, in this embodiment, the manufacturing process of the sensing module 120B may include, for example, disposing a part of the conductive structure 127 in the through-holes 1226 of the first substrate 122B, as shown in FIG. 11A. The sensing layer 124 is disposed on the first surface S1 of the first substrate 122B and electrically connected to the conductive structure 127 located in the through-holes 1226, as shown in FIG. 11B. Another part of the conductive structure 127 is formed on the second substrate 126, and a combination of the sensing layer 124 and the first substrate 122B is disposed on the second substrate 126, as shown in FIG. 11C. The control layer 123 is disposed on the second substrate 126, and the electrical connection element 125 is disposed to connect the control layer 123 and the conductive structure 127 located on the second substrate 126, as shown in FIG. 11D.

In summary, in the detection system of the disclosure, the detection system includes an illumination module, a sensing module, and a processing part. The illumination module is configured to provide an illumination beam to an element under test. The sensing module is configured to sense the element under test to obtain an electrical signal, and the processing part is configured to generate a sensing result according to the electrical signal. The sensing module includes a carrier mechanism, a first substrate, a control layer, a sensing layer, and an electrical connection element. The sensing layer has a sensing surface, and the sensing surface is the surface closest to the element under test in the sensing module. Thus, the circuits or other components in the sensing module do not exceed the height of the sensing surface, to ensure that the circuits or other components do not come into contact with the element under test, thereby realizing a non-contact detection method that is beneficial to rapid massive detection.

Although the disclosure has been described with reference to the above embodiments, they are not intended to limit the disclosure. Any person skilled in the art may make some modifications and refinements without departing from the spirit and scope of the disclosure. Therefore, the scope of protection of the disclosure shall be defined by the appended claims.

What is claimed is:

1. A detection system, configured to detect an element under test, the detection system comprising:
an illumination module configured to provide an illumination beam to the element under test, the illumination beam comprising a plurality of sub-beams of different wavelengths;
a sensing module configured to sense the element under test to obtain an electrical signal, the sensing module comprising:
a carrier mechanism;
a first substrate disposed on the carrier mechanism, the first substrate having a first surface and a second surface opposite to each other, the second surface facing the carrier mechanism;
a control layer disposed on the second surface of the first substrate;
a sensing layer disposed on the first surface of the first substrate, the sensing layer having a sensing surface, the sensing surface being a surface closest to the element under test in the sensing module; and
an electrical connection element electrically connected to the sensing layer and the control layer; and
a processing part electrically connected to the illumination module and the sensing module, and configured to generate a sensing result according to the electrical signal.

2. The detection system according to claim 1, wherein during detection, the illumination module provides the illumination beam with different light intensities to the element under test, so that the sensing module obtains a plurality of electrical sub-signals correspondingly, and the electrical signal comprises the electrical sub-signals.

3. The detection system according to claim 2, wherein during detection, a difference between the light intensities of the illumination beam is greater than 10%.

4. The detection system according to claim 1, wherein wavelengths of the sub-beams are in a range of 360 nm to 450 nm, 500 nm to 600 nm, 600 nm to 650 nm, or 1000 nm to 1600 nm.

5. The detection system according to claim 1, wherein the element under test is located between the illumination module and the sensing module, and the illumination beam is transmitted to the element under test from a side of the element under test that is away from the sensing module.

6. The detection system according to claim 1, wherein the illumination beam is transmitted to the element under test from a side surface of the element under test.

7. The detection system according to claim 1, wherein the illumination module is disposed on the sensing module,
the illumination module comprises a light-emitting element and a light-guiding element,
the light-emitting element provides the illumination beam, and
the light-guiding element is disposed on a transmission path of the illumination beam and guides the illumination beam to be transmitted to the element under test from a side of the element under test that is close to the sensing module.

8. The detection system according to claim 1, wherein a thickness of the sensing layer is greater than or equal to 10 μm.

9. The detection system according to claim 1, wherein the sensing layer comprises a sensing pattern and a light-transmitting layer,
the sensing pattern is electrically connected to the electrical connection element,
the light-transmitting layer covers the sensing pattern, and
the sensing surface is located on a surface of the light-transmitting layer.

10. The detection system according to claim 1, wherein the electrical connection element has at least one bending point.

11. The detection system according to claim 1, wherein the electrical connection element is disposed on the first substrate and is connected to the first surface and the second surface.

12. The detection system according to claim 11, wherein the first substrate has a third surface connected to the first surface and the second surface,
the third surface is perpendicular to the first surface and the second surface, and
the electrical connection element is further connected to the third surface.

13. The detection system according to claim 1, wherein the sensing module further comprises a second substrate and a conductive structure,
the second substrate is disposed between the first substrate and the control layer,
the conductive structure is connected to the first substrate,
the electrical connection element is connected to the second substrate, and
the conductive structure is connected between the sensing layer and the electrical connection element.

14. The detection system according to claim 13, wherein the first substrate comprises a first portion and a second portion connected to each other,
a thickness of the first portion is greater than a thickness of the second portion,
the sensing layer is connected to the first portion,
the conductive structure is connected to the first surface and is continuously connected to the first portion and the second portion, and
the electrical connection element is connected to the conductive structure located on the second portion.

15. The detection system according to claim 14, wherein a width of the second portion is greater than 20 μm, and a vertical distance between the first surface located on the second portion and the sensing surface is greater than 50 μm.

16. The detection system according to claim 13, wherein the first substrate has a plurality of through-holes, and the conductive structure is connected to the second surface and is also located in the through-holes to connect the sensing layer.

17. The detection system according to claim 1, wherein the carrier mechanism, the control layer, the first substrate, the electrical connection element, and the sensing layer are sequentially stacked along a first direction, and the sensing surface is a surface of the sensing module that is closest to the element under test in the first direction.
